(19) United States
(12) Patent Application Publication
(10) Pub. No.: US 2008/0068805 A1
(43) Pub. Date: Mar. 20, 2008

(54) HEAT SINK ASSEMBLY FOR MULTIPLE ELECTRONIC COMPONENTS

(75) Inventors: Xiao Xu, Shenzhen (CN); Yong-Dong Chen, Shenzhen (CN); Guang Yu, Shenzhen (CN); Shih-Hsun Wung, Tu-Cheng (TW); Chun-Chi Chen, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: Foxconn Technology Co., Ltd., Tu-Cheng (TW)

(21) Appl. No.: 11/309,699

(22) Filed: Sep. 15, 2006

(51) Int. Cl. H05K 7/20

(52) U.S. Cl. 361/710

(57) ABSTRACT

A heat sink assembly includes a primary heat sink and a subordinate heat sink. The primary heat sink comprises a base with a main surface; the subordinate heat sink is attached to the primary heat sink and movable relative to the primary heat sink in a direction perpendicular to the main surface of the primary heat sink; the subordinate heat sink comprises a base with a main surface parallel to the main surface of the primary heat sink. The main surfaces of the primary heat sink and the subordinate heat sink face in a similar direction.

### FIELD OF THE INVENTION

The present invention relates generally to a heat sink assembly, and more particularly to a heat sink assembly adapted for removing heat from multiple electronic heat-generating components of differing heights.

### DESCRIPTION OF RELATED ART

Electronic component includes numerous circuits operating at high speed and generating substantial heat. In many applications, it is desirable to employ a heat sink to remove heat from electronic heat-generating components, such as central processing units (CPUs) etc., to assure that the components function properly and reliably. A typical heat sink comprises a base for contacting with the heat-generating component to absorb the heat originated from the heat-generating component and a plurality of parallel planar fins attached to the base by soldering or adhering. Alternatively, the fins can be integrally formed with the base by metal extrusion, such as aluminum extrusion. The fins are used for dissipating the heat to ambient air.

With the development of various types of electronic modules, an array of many discrete components may be mounted to a surface of a single circuit board. In some circumstances, more than one of the components must be cooled. Since the components are generally of different heights and their top surfaces are thus at different levels, conventional heat sinks can not meet the requirement to intimately contact with the top surfaces of the components simultaneously to remove the heat from all the components. Thus, more than one of individual heat sinks need to be employed to remove heat from each component. Accordingly, a large amount of space is required to install the heat sinks, thus restricting space for other components; furthermore, it is both expensive and time-consuming to attach individual heat sinks to each component.

What is needed is a heat sink assembly with an improved structure able to cool an array of components with different heights.

### SUMMARY OF THE INVENTION

A heat sink assembly includes a primary heat sink and a subordinate heat sink. The primary heat sink comprises a base with a main surface; the subordinate heat sink is attached to the primary heat sink and movable relative to the primary heat sink in a direction perpendicular to the main surface of the primary heat sink. The subordinate heat sink comprises a base with a main surface parallel to the main surface of the primary heat sink. The main surfaces of the primary heat sink and the subordinate heat sink face in a similar direction.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is an assembled isometric view of a heat sink assembly in accordance with a preferred embodiment of the present invention;

FIG. 2 is similar to FIG. 1, but viewed from another aspect and having screws thereof separate from a base thereof; and

FIG. 3 is an exploded, isometric view of FIG. 1.

### DETAILED DESCRIPTION OF THE INVENTION

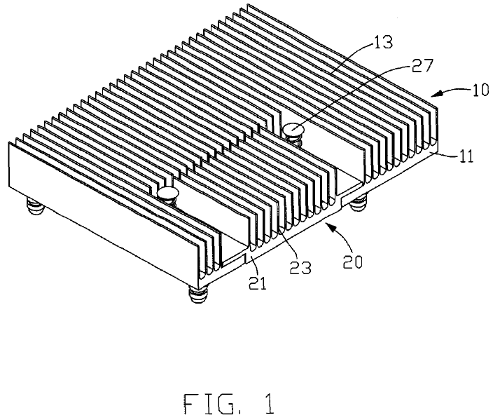

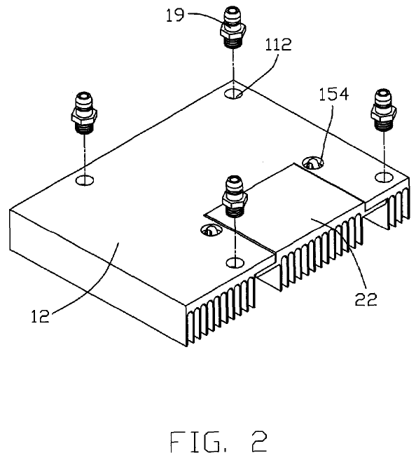

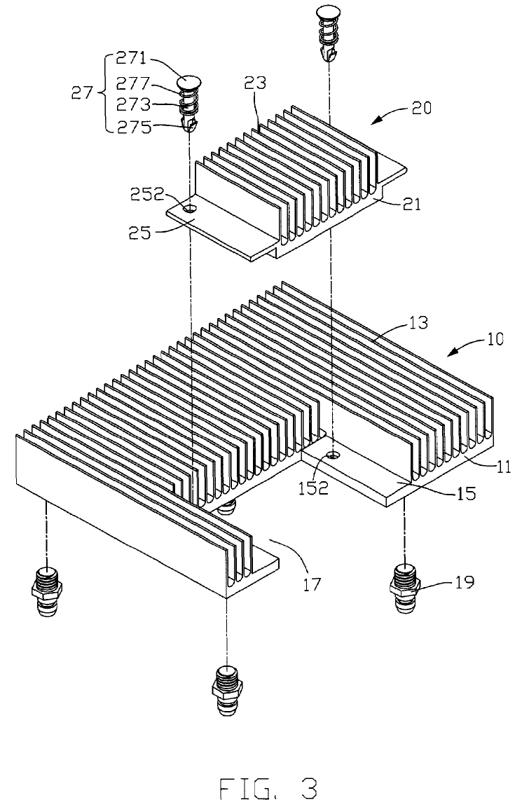

Referring to FIG. 1, a heat sink assembly in accordance with a preferred embodiment of the invention comprises a primary heat sink 10, a subordinate heat sink 20 and two fixtures 27 movably connecting the primary heat sink 10 and subordinate heat sink 20 together. Characteristics of the heat sink assembly are illustrated in more detail in FIGS. 2 and 3.

The primary heat sink 10 is made of a thermally conductive metal such as aluminum, and comprises a base 11, a plurality of parallel fins 13 integrally extending from the base 11 and a cutout 17 recessed from a lateral side of base 11.

The base 11 is board-shaped. The base 11 comprises a bottom surface 12 for contacting a heat-generating electronic component (not shown) and a top surface (not labeled). The base 11 in each corner thereof defines a blind hole 112 with inner thread extending from the bottom surface 12 of the base 11 in a direction perpendicular to the bottom surface 12 of the base 11. Each blind hole 112 engages with a screw 19 to mount the heat assembly to a circuit board (not shown) on which the heat-generating electronic component is mounted. The fins 13 are formed integrally from the top surface of the base 11 and are spaced from each other. The cutout 17 of the primary heat sink 10 can be in various shapes corresponding to the shape of the subordinate heat sink 20. In the preferred embodiment of the present invention, the cutout 17 is rectangular-shaped so as be capable of receiving the subordinate heat sink 20. A pair of supports 15 are formed on the base 11 at opposite lateral sides of the cutout 17, for supporting the subordinate heat sink 20 thereon. A mounting hole 152 extending from the top surface to the bottom surface 12 of the base 11, is defined on each support 15 for receiving one of the fixtures 27 to mount the subordinate heat sink 20 onto the primary heat sink 10. A pair of annular rings 154 are provided on the base 11, and are disposed in the mounting holes 152. The annular rings 154 are located near the bottom surface 12 of the primary heat sink 10.

The subordinate heat sink 20 is made of a thermally conductive metal such as aluminum, and comprises a rectangular base 21, a plurality of parallel fins 23 and two shoulders 25. The base 21 has a bottom surface 22 for contacting another heat-generating electronic component (not shown) and a top surface (not labeled). The fins 23 integrally extend from the top surface of the base 21. Each fin 21 is oriented parallel to and spaced with a predetermined distance from the adjacent fins 21. The shoulders 25 are horizontally and outwardly extended from opposite edges of the base 21. The shoulders 25 are mounted on the supports 15 of the primary heat sink 10. A mounting hole 252 is defined on each shoulder 25, for cooperating with one mounting hole 152 of the primary heat sink 10 to receive one fixture 17.

Each fixture 27 includes a pin formed from a molded plastic material and a spring 277. The pin has a head 271 at one end thereof, an elongated shaft 273 extending axially from the head 271 and a barb 275 at an opposite end thereof. The spring 277 closely encircles the shaft 273 and is held between the head 271 and the barb 275.

In order to assemble the heat sink assembly, the base 21 of the subordinate heat sink 20 should be properly accommodated in the cutout 17 of the primary heat sink 10. The shoulders 25 of the subordinate heat sink 20 are then rested on the supports 15 of the primary heat sink 10. The mounting holes 252 of the shoulders 25 are aligned with the mounting holes 152 of the supports 15. The shafts 273 of the fixtures 27 can then be subsequently extended into their respective mounting holes 252, 152, during which the barbs 275 are deformed. After the barbs 275 slide over the annular rings 154, the barbs 275 rebound and are blocked by the annular rings 154 disposed in the mounting holes 152 of the primary heat sink 10. Thus, the fixtures 27 lock the subordinate heat sink 20 to the primary heat sink 10. Each spring 277 is slightly compressed between the head 271 and the shoulder 25 to urge the subordinate heat sink 20 toward the primary heat sink 10 and to make the shoulders 25 of the subordinate heat sink 20 contact with the supports 15 of the primary heat sink 10. In order to protect the electronic components from being interfered with by the fixtures 27, the fixtures 27 terminate in the mounting holes 152 and do not stretch out of the mounting holes 152.

In the heat sink assembly, the bottom surface 22 of the subordinate heat sink 20 is disposed at a level below the bottom surface 12 of the primary heat sink 10, when the shoulders 25 of the subordinate heat sink 20 rest on the supports 15 of the primary heat sink 10. The bottom surface 22 of the subordinate heat sink 20 can also be at a level coplanar with or higher than the bottom surface 12 of the primary heat sink 10, in which case the shoulders 25 of the subordinate heat sink 20 can be separated from the supports 15 of the primary heat sink 10 by further compressing the springs 27. In other words, the subordinate heat sink 20 is vertically movable relative to the primary heat sink 10 in a direction perpendicular to the bottom surface 12 of the primary heat sink 10 by changing compression of the springs 27. Therefore, the heat sink assembly can be used to cool two electronic components having top surfaces at identical or different levels. The springs 277 provide a downwardly pressing force on the subordinate heat sink 20 so it can intimately contact with the corresponding electronic component.

In other embodiment of the present invention, the heat sink assembly can be provided with more than one cutout and an amount of subordinate heat sinks according to the number of electronic components to be cooled.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat sink assembly comprising:
a primary heat sink having a base, the base defining a cutout therein and comprising a bottom surface adapted for contacting an electronic component;
a subordinate heat sink comprising a base, the base being received in the cutout of the primary heat sink and having a bottom surface adapted for contacting another electronic component; and
two fixtures connecting the primary heat sink and the subordinate heat sink together, and allowing the subordinate heat sink to move relative to the primary heat sink and thereby allowing a relationship between the bottom surface of the subordinate heat sink and the bottom surface of the primary heat sink to be changed in a direction perpendicular to the bottom surface of the primary heat sink.

2. The heat sink assembly as claimed in claim 1, wherein the cutout of the primary heat sink forms a support at each of opposite lateral edges thereof.

3. The heat sink assembly as claimed in claim 2, wherein the base of the subordinate heat sink has two shoulders extending laterally and horizontally from opposite lateral sides thereof, each of the shoulders is mounted on a corresponding support.

4. The heat sink assembly as claimed in claim 3, wherein the shoulders of the subordinate heat sink and the supports of the primary heat sink each define a mounting hole therein.

5. The heat sink assembly as claimed in claim 4, wherein the mounting hole of the primary heat sink is provided with an annular ring therein, the annular ring being located near the bottom surface of the primary heat sink.

6. The heat sink assembly as claimed in claim 5, wherein the fixtures subsequently extend through corresponding mounting holes of the shoulder and the support and terminate in the mounting holes without stretching out of the mounting holes.

7. The heat sink assembly as claimed in claim 5, wherein the fixture includes a pin body having a head locked above the shoulder, a barb blocked by the ring of the mounting hole of the support and a shaft between the head and the barb extending into the mounting holes of the shoulder and the support, a spring encircling the shaft and compressed between the head and the shoulder to urge the subordinate heat sink toward the primary heat sink.

8. The heat sink assembly as claimed in claim 1, wherein the base of the primary heat sink at each corner defines a blind hole extending from the bottom surface thereof and with inner thread.

9. The heat sink assembly as claimed in claim 7, wherein each blind hole engages with a screw to mount the heat sink assembly on a circuit board.

10. A heat sink assembly comprising:
a primary heat sink having a base with a main surface adapted for contacting with a first electronic component; and
a subordinate heat sink attached to the primary heat sink and movable relative to the primary heat sink in a direction perpendicular to the main surface of the primary heat sink, the subordinate heat sink comprising a base with a main surface parallel to the main surface of the primary heat sink and adapted for contacting with a second electronic component;
wherein the main surfaces of the primary heat sink and the subordinate heat sink face in a similar direction.

11. The heat sink assembly as claimed in claim 10, wherein the base of the primary heat sink forms a cutout for receiving the base of the subordinate heat sink.

12. The heat sink assembly as claimed in claim 11, wherein the cutout of the primary heat sink forms a pair of supports at opposite lateral sides thereof.

13. The heat sink assembly as claimed in claim 12, wherein the base of the subordinate heat sink has two shoulders respectively extending laterally and horizontally from opposite lateral sides thereof.

14. The heat sink assembly as claimed in claim 13, wherein the shoulders are mounted on the supports by two fixtures.

15. A heat sink assembly comprising:
a primary heat sink having a bottom surface adapted for contacting with a first heat-generating electronic component; and
a subordinate heat sink movably mounted on the primary heat sink, having a bottom surface adapted for contacting with a second heat-generating electronic component.

16. The heat sink assembly of claim 15, wherein the primary heat sink defines a cutout receiving the subordinate heat sink therein.

17. The heat sink assembly of claim 16, wherein the subordinate heat sink is movably mounted on the primary heat sink by a fastener, the fastener having a bottom barb engaging in the subordinate heat sink, a shaft extending upwardly from the barb through the subordinate heat sink and the primary heat sink, a head located at a top of the shaft and above the primary heat sink, and a spring surrounding the shaft and compressed between the primary heat sink and the head of the fastener.

18. The heat sink assembly of claim 15, wherein the subordinate heat sink is movable relative to the primary heat sink along a direction perpendicular to the bottom surface of the primary heat sink.

19. The heat sink assembly of claim 16, wherein the subordinate heat sink is movable relative to the primary heat sink along a direction perpendicular to the bottom surface of the primary heat sink.
